(19) United States
(12) Patent Application Publication
(10) Pub. No.: US 2024/0116752 A1
(43) Pub. Date: Apr. 11, 2024

(54) PACKAGED CAVITY STRUCTURE AND MANUFACTURING METHOD THEREOF

(71) Applicant: Zhuhai ACCESS Semiconductor Co., Ltd, Guangdong (CN)

(72) Inventors: Xianming CHEN, Guangdong (CN); Lei FENG, Guangdong (CN); Jiangjiang ZHAO, Guangdong (CN); Benxia HUANG, Guangdong (CN); Gao HUANG, Guangdong (CN); Yejie HONG, Guangdong (CN)

(21) Appl. No.: 18/377,419

(22) Filed: Oct. 6, 2023

(30) Foreign Application Priority Data
Oct. 11, 2022 (CN) 2022112428096

(51) Int. Cl. B81C 1/00; B81B 7/00

(52) U.S. Cl. CPC B81C 1/00301; B81B 7/0061; B81C 1/00309; B81B 2207/092; B81C 2203/0118

(57) ABSTRACT

A packaged cavity structure includes an embedded packaging frame having a first cavity and a first conductive post respectively penetrating an insulation layer in a height direction, a chipset within the first cavity, a first circuit layer on an upper surface of the embedded packaging frame, a first dielectric layer on the first circuit layer, a second circuit layer on the first dielectric layer, a through-hole penetrating the first dielectric layer and the insulation layer, a third circuit layer on a lower surface of the embedded packaging frame, a support post enclosure on the third circuit layer, and a packaging layer formed along the outside of the support post enclosure. A second cavity communicating with the through-hole is formed between the packaging layer and the lower surface of the embedded packaging frame, and the chipset includes a first chip and a second chip provided in a back-to-back stack.

### CROSS-REFERENCE TO RELATED APPLICATION AND CLAIM OF PRIORITY

This application claims the benefit under 35 USC § 119 of Chinese Patent Application No. 2022112428096, filed on Oct. 11, 2022, in the China Intellectual Property Office, the entire disclosure of which is incorporated herein by reference for all purposes.

### BACKGROUND

### 1. Technical Field

The present application relates to the technical field of electronic device packaging, in particular to a packaged cavity structure and a manufacturing method thereof.

### 2. Background Art

Micro-electromechanical system (MEMS) sensors are widely used in medical, automotive, communication and computer fields. The MEMS sensors include an MEMS microphone, an MEMS barometer, an MEMS hygrometer and an MEMS gas sensor. The packaging structure mainly includes a package substrate, an MEMS sensing chip, an ASIC (application-specific integrated circuit) chip, a protective casing and a channel for the MEMS sensing chip to realize environmental perception. The current electronic products present the development trend of being short, light and thin. Therefore, the requirements for miniaturization and high-density integration of an MEMS sensing packaging structure are proposed.

At present, packaging of the MEMS sensor and the ASIC chip is mainly to attach the MEMS sensor chip and the ASIC chip on a package substrate, realize the electrical connection between the MEM sensor chip and the ASIC chip and the package substrate by means of wire bond, and then attach a protective casing to protect the packaged device, and reserve a through-hole on the substrate or the protective casing to realize the interaction between the MEMS sensor chip and the external environment. Therefore, the existing cavity structure with packaging has large packaging volume, which cannot meet the development needs of semiconductor packaging. Each sensor unit requires a separate protective cover, which is inefficient and costly to manufacture; the way of applying the protective cover is poor in processing precision and cannot meet the development requirements of high-density packaging.

### SUMMARY

In view of the above, it is an object of the present application to provide a packaged cavity structure and a manufacturing method thereof.

Based on the above object, the present application provides a method for manufacturing a packaged cavity structure, which includes the following steps:
(a) preparing an embedded packaging frame; the embedded packaging frame including a first cavity and a first conductive post respectively penetrating an insulation layer along a height direction;
(b) embedding a chipset at the bottom of the first cavity; the chipset including a first chip and a second chip provided in a stack, and the back faces of the first chip and the second chip being adhered to each other so that the terminal faces thereof being opposite to each other;
(c) forming a packaging layer in a gap between the chipset and the first cavity; the packaging layer having a blind hole exposing a terminal of the second chip;
(d) forming a first circuit layer and a second conductive post on an upper surface of the embedded packaging frame, wherein the first circuit layer is in conductive connection with a terminal of the second chip;
(e) laminating a first dielectric layer on an upper surface of the first circuit layer; wherein an upper surface of the first dielectric layer is flush with an upper surface of the second conductive post;
(f) forming a second circuit layer on an upper surface of the first dielectric layer, forming a third circuit layer on a lower surface of the embedded packaging frame, and forming a support post enclosure surrounding the first cavity on the third circuit layer;
(g) forming a through-hole penetrating the first dielectric layer and the insulation layer successively in a height direction, wherein the through-hole is surrounded by the above-mentioned support post enclosure; and
(h) forming a packaging layer along an outer side of the support post enclosure under the embedded packaging frame, and forming a second cavity between the packaging layer and the embedded packaging frame.

An embodiment of the present application further provides a packaged cavity structure including an embedded packaging frame having a first cavity and a first conductive post respectively penetrating an insulation layer in a height direction; a chipset provided within the first cavity; a first circuit layer provided on an upper surface of the embedded packaging frame; a first dielectric layer provided on the first circuit layer; a second circuit layer provided on the first dielectric layer; a through-hole penetrating the first dielectric layer and the insulation layer; a third circuit layer on a lower surface of the embedded packaging frame; a support post enclosure on the third circuit layer; and a packaging layer formed along the outside of the support post enclosure;
wherein a second cavity communicating with the through-hole is formed between the plastic packaging layer and the lower surface of the embedded packaging frame, and the chipset includes a first chip and a second chip provided in a back-to-back stack.

It can be seen from the above that the packaged cavity structure provided in the embodiments of the present application is that a chipset stack composed of a first chip and a second chip which are provided in a stack is embedded and packaged inside a package substrate, an electrical connection with the package substrate is achieved through a blind hole of the package layer, a copper post enclosure is processed on the top (i.e. the lower surface) of the embedded package substrate, a second cavity can be formed after packaging, and sensing with an external environment is achieved through the second cavity and a through-hole; a high-density integrated package can be achieved, with high precision, and the advantages of miniaturization of package volume and high package efficiency.

### BRIEF DESCRIPTION OF THE DRAWINGS

In order to explain the present application or the technical solutions in the related art more clearly, a brief description will be given below with reference to the description of the embodiments or the related art; obviously, the drawings in the description below are merely the embodiments of the present application, and it would have been obvious for a person skilled in the art to obtain other drawings according to these drawings without involving any inventive effort.

FIG. 1 is a schematic diagram showing the structure of a mainstream packaging mode of an MEMS sensor and an ASIC chip in the prior art;

FIG. 2 is a cross-sectional view showing a packaged cavity structure according to an embodiment of the present disclosure;

FIGS. 3A-3I are schematic cross-sectional views showing intermediate structures of various steps of a method for manufacturing a packaged cavity structure according to an embodiment of the present application.

### DETAILED DESCRIPTION

The objects, technical solutions and advantages of the present application will become more apparent from the following detailed description when taken in conjunction with the accompanying drawings.

It should be noted that, unless otherwise defined, technical or scientific terms used in the examples of the present application shall have the ordinary meaning as understood by a person skilled in the art to which the present application belongs. The use of the terms “first”, “second”, and the like in the embodiments herein does not denote any order, quantity, or importance, but rather is used to distinguish one element from another. The word “including” or “includes”, and the like, means that the elements or items preceding the word encompass the elements or items listed after the word and equivalents thereof, but do not exclude other elements or items. “Connected” or “coupled” and like terms are not limited to physical or mechanical connections, but may include electrical connections, whether direct or indirect. “Up”, “down”, “left”, “right”, etc. are only used to indicate a relative positional relationship, which may change accordingly when the absolute position of the object being described changes.

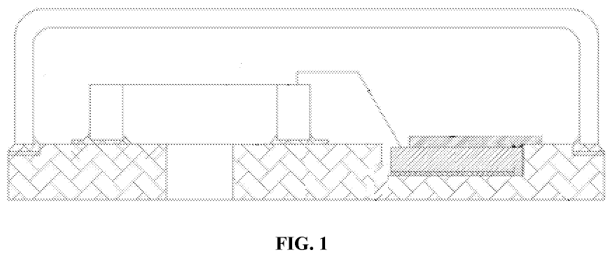

FIG. 1 is a schematic diagram showing the structure of a mainstream packaging mode of an MEMS sensor and an ASIC chip in the prior art.

As shown in FIG. 1, in some mainstream packaging methods of an MEMS sensor and an ASIC chip, with regard to multiple units formed by the electrical connection between the MEM sensing chip and the ASIC chip and a package substrate via bonding wires, a protective cover needs to be separately applied to each unit for protection and form a cavity to realize packaging.

It can be seen that in the packaging manner of the MEMS sensor and the ASIC chip in the prior art, a protective cover needs to be separately applied to each unit, which has the problems of low processing efficiency and high cost; in addition, there are some problems in the way of applying the protective cover, such as poor processing precision and inability to meet the development requirements of high-density packaging, and there are also problems in the way of applying the protective cover, such as large packaging volume and inability to meet the development requirements of small, light and thin semiconductor packaging.

On this basis, the embodiments of the present application provide a method for manufacturing a packaged cavity structure, wherein a packaged cavity can be formed after packaging by machining a copper post enclosure on the top of an embedded package substrate, and the existing packaged cavity structure can be solved to a certain extent by separately applying a protective cover to each unit, with low processing efficiency and high cost; poor processing precision cannot meet the development of high-density packaging requirements; the volume of package is large, which cannot meet the needs of the development of semiconductor packages.

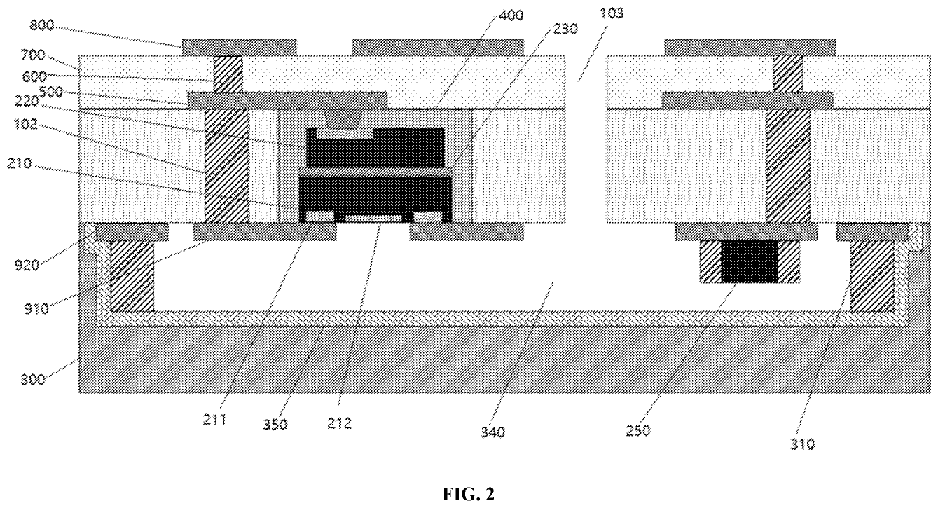

FIG. 2 is a cross-sectional view showing a packaged cavity structure according to an embodiment of the present disclosure.

As shown in FIG. 2, the embodiments of the present application provide a packaged structure that may include an embedded packaging frame, a chipset embedded within the embedded packaging frame, and a packaged layer 300 surrounding a lower surface of the embedded packaging frame. Wherein the chipset includes a first chip 210 and a second chip 220 provided in a stack, and the terminals of the first chip 210 and the second chip 220 are provided opposite to each other.

The packaged cavity structure includes a first cavity and a first conductive post 102 respectively penetrating an insulation layer forming the embedded packaging frame in a height direction. A chipset provided within the first cavity further includes a packaging layer 400 provided within a gap between the chipset and the first cavity; a first circuit layer 500 and a second conductive post 600 provided on the upper surface of the embedded packaging frame; a first dielectric layer 700 and a second circuit layer 800 provided on the first circuit layer 500; a through-hole 103 that sequentially penetrates through the first dielectric layer 700 and the insulation layer of the embedded packaging frame is further included.

A third circuit layer provided on the lower surface of the embedded packaging frame and a support post enclosure 310 provided around the lower surface of the embedded packaging frame; wherein the third circuit layer may include a functional circuit layer 910 and a circuit enclosure 920, and the support post enclosure 310 may be correspondingly provided on the circuit enclosure 920. That is, a support post enclosure is provided on the third circuit layer. A passive element 250 provided on a lower surface of the third circuit layer; a packaging layer 300 provided on the lower surface of the embedded packaging frame and the outsides of the third circuit layer and the support post enclosure 310; that is, the packaging layer 300 is formed along the outside of the support post enclosure. A second cavity 340 in communication with the through-hole 103 is provided between the packaging layer 300 and the lower surface of the embedded packaging frame.

It should be understood that a plurality of chipsets may be provided, as specifically determined according to actual requirements. Accordingly, the first cavity may be provided in a plurality, respectively for embedding a plurality of chipsets. However, the second cavity 340 formed between the packaging layer 300 and the lower surface of the package substrate can cover all the chipsets, thereby achieving the formation of a high-density integrated package.

According to a packaged cavity structure provided in an embodiment of the present application, wherein a chipset stack composed of a first chip 210 and a second chip 220 which are provided in a stack is embedded and encapsulated inside an package substrate, an electrical connection with the package substrate is achieved through a blind hole of a packaging layer 400, and a copper post enclosure is processed on the top (equivalent to the lower surface) of the embedded package substrate, and the packaged cavity can be formed after packaging; a high-density integrated packaging can be achieved, with high precision, and the advantages of miniaturization of package volume and high package efficiency.

In some embodiments, the embedded packaging framework is a polymer framework. The frame may be composed of a polymer applied as a polymer sheet or may be composed of a glass fiber reinforced polymer applied as a prepreg. It may have one or more layers.

The conductive posts referred to in this embodiment (e.g., the first conductive post 102 or the second conductive post 600) may include at least one copper through-hole post as an IO channel to enable conduction from layer to layer, and the size and/or shape of the plurality of conductive posts may be the same or different. The conductive post can be a solid copper post or a hollow post plated with copper on the surface; preferably, the conductive posts include a plurality of copper through-hole posts as IO channels, and the ends of the conductive posts may be flush with the encapsulation layer.

In the chipset, the first chip 210 may be a sensing chip (e.g., an MEMS sensing chip) having a plurality of terminals 211 and a sensing component 212. In addition, the terminal face of the first chip 210 is attached to the bottom of the first cavity. The surface of the sensing component 212 is exposed, i.e., the surface of the sensing component is not covered by the third circuit layer. That is, the sensing part surface of the first chip is exposed to the second cavity to communicate with the outside through the through-hole. As such, the sensing chip can sense an external environmental load through the second cavity 340 and the through-hole 103 and then output an electrical signal to the second chip 220.

The connection between the second chip 220 and the first chip 210 by an adhesive material 230. In addition, the second chip 220 may be smaller in size (e.g., length) than the first chip 210 and the adhesive material 230, and the adhesive material 230 may be the same size as the first chip 210. The viscosity of the adhesive material 230 may be greater than the viscosity of the packaging layer 400, which may avoid damage to the chip or the like caused by the packaging layer 400 being too hard to be bonded to the adhesive material 230. The second chip 220 can be an ASIC chip which can amplify and modulate the electrical signal output by the MEMS chip into a required standard output signal.

In some embodiments, a second dielectric layer 350 provided between the packaging layer 300 and the third circuit layer and the support post enclosure 310 is also included. That is, a second dielectric layer is also included between the packaging layer 300 and the second cavity. The second dielectric layer 350 may be a covering film. The covering film may be a polytetrafluoroethylene (PTFE) film or a polyimide (PI) film, etc. As such, the packaging layer 300 can be better packaged by the covering film and the stress can be released efficiently.

In some embodiments, the support post enclosure 310 may be a copper support post enclosure, which may serve to dissipate heat while being supported. Taking the surface on which the embedded packaging frame is located as a reference surface, the forward projection of the support post enclosure 310 on the reference surface partially overlaps with the forward projection of the circuit enclosure 920 on the reference surface.

In some embodiments, a second metal seed layer may be provided between the embedded packaging frame and the first circuit layer 500, and a first metal seed layer may also be provided between the embedded packaging frame and the third circuit layer. As such, it is possible to improve the stability, reliability, etc. of the conductive connection between the first conductive post 102 and the first circuit layer 500, and to improve the stability, reliability, etc. of the conductive connection between the first conductive post 102 and the third circuit layer.

In some embodiments, a third metal seed layer may also be provided between the first dielectric layer 700 and the second circuit layer 800. As such, it is possible to improve stability, reliability, etc. of the conductive connection between the second conductive post 600 and the first circuit layer 500 and the second circuit layer 800.

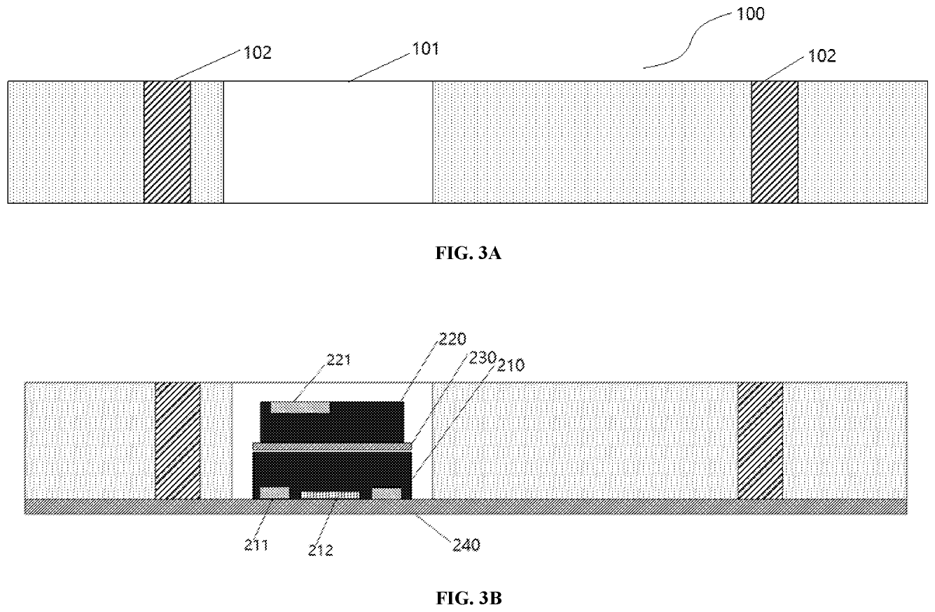

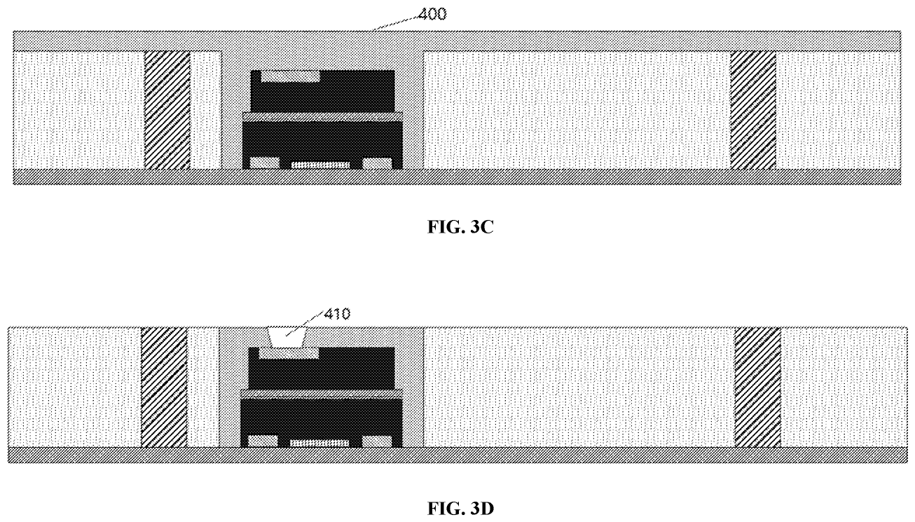

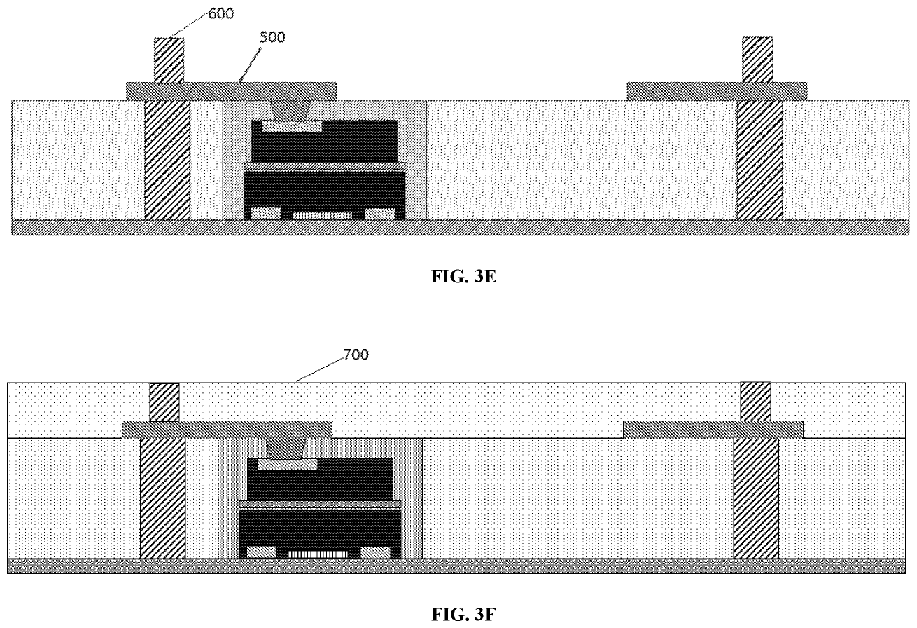

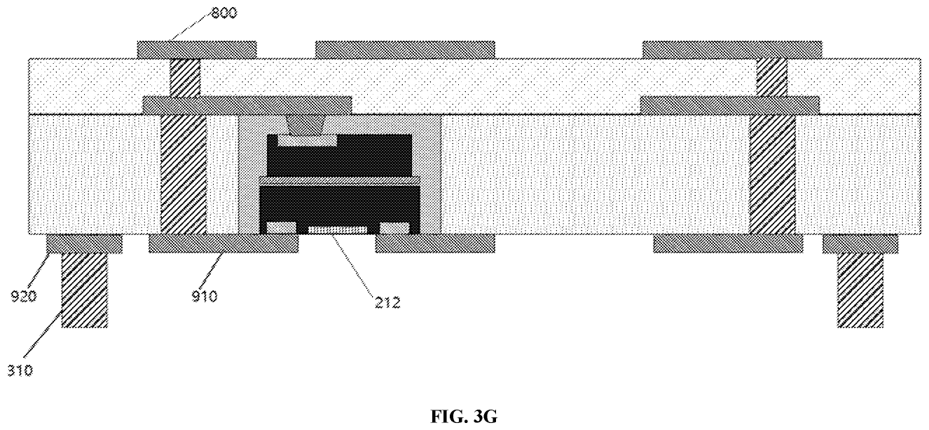

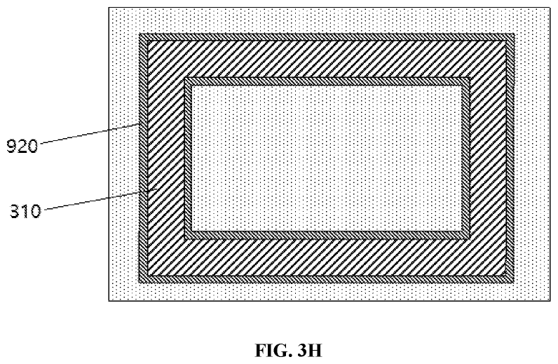

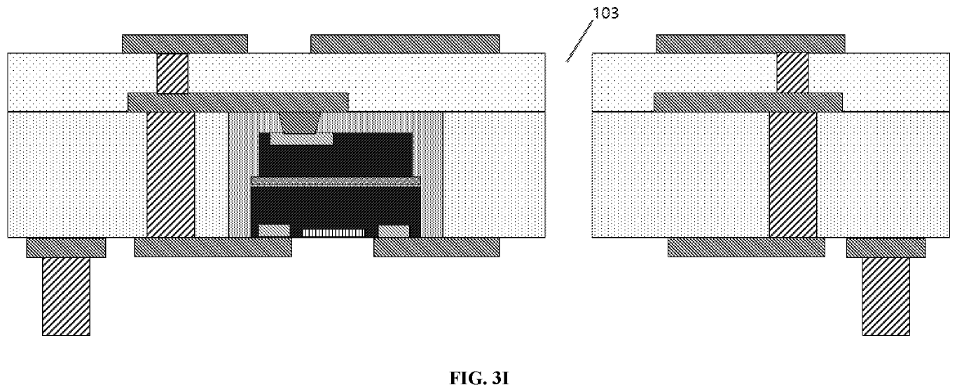

Referring to FIGS. 3A-3I, a schematic cross-sectional view of an intermediate structure at various steps of a method for manufacturing a packaged structure according to an embodiment of the present application is shown.

The manufacturing method includes the steps of: preparing an embedded packaging frame 100 including a first cavity 101 and a first conductive post 102 respectively penetrating the embedded packaging frame in a height direction-step (a), as shown in FIG. 3A.

In general, a plurality of first cavities 101 may be provided for subsequent mounting of a chipset, and the dimensions of the plurality of first cavities 101 may be the same or different, and are determined according to the shape and size of the chipset to be embedded, and are not limited herein. The embedded packaging frame 100 may be composed of a polymer applied as a polymer sheet or may be composed of a glass fiber reinforced polymer applied as a prepreg. It may have one or more layers.

In general, the embedded packaging frame 100 may be manufactured using Zhuhai ACCESS's through-hole post technology, either pattern plating or panel plating, followed by selective etching, through-holes may be manufactured as through-hole posts, followed by lamination using a dielectric material such as a polymer film or a prepreg composed of woven glass fiber bundles in a polymer matrix for added stability. In one embodiment, the dielectric material is Hitachi 705G. In another embodiment, MGC832 NXA NSFLCA is used. In a third embodiment, Sumitomo GT-K may be used. In another embodiment, Sumitomo LAZ-4785 series membranes are used. In another embodiment, the Sumitomo LAZ-6785 series is used. Alternative materials include Taiyo's HBI and Zaristo-125 or Ajinomoto's ABF GX material series.

There are a number of advantages to manufacturing a through-hole post rather than a drill-in technique. In the through-hole post technology, the through-hole post technology is faster since all through-holes can be made at the same time, whereas the drill-in technology requires separate drilling. Further, since the drilled through-holes are all cylindrical, the through-hole post may have any shape. In practice, all drilled through-holes have the same dimensions (within tolerances), while the through-hole posts may have different shapes and dimensions. In addition, in order to strengthen, it is preferred that the polymer matrix is fiber reinforced, typically with woven strands of glass fibers. A through-hole post is characterized as having smooth and vertical sides when a prepreg including fibers within a polymer is laid on an upstanding through-hole post and cured. However, when drilling composite materials, the drilled through-holes are typically slanted; there is typically a rough surface, which causes stray inductance, leading to noise.

In general, the first conductive post 102 has a width in the range of 25 microns to 500 microns. In the case of primary posts, each of the conductive posts may have a diameter of 25 microns to 500 microns as required for drilling and as is common in conductive posts.

Next, a chipset is embedded in the bottom of the first cavity 101—step (b), as shown in FIG. 3B.

In general, embedding a chipset at the bottom of the first cavity 101 in the step (b) includes:
(b₁) applying an adhesive layer 240 on a lower surface of the embedded packaging frame 100; in general, the adhesive layer 240 may be a single-sided tape, typically a commercially available transparent film that is thermally decomposable or decomposable under ultraviolet radiation; the adhesive layer 240 can temporarily support and secure the chipset; and
(b₂) attaching a terminal face of the second chip 220 of the chipset on the exposed adhesive layer 240 in the first cavity 101 to attach a chipset at the bottom of the first cavity 101. The chipset includes a first chip 210 and the second chip 220 provided in a stack, and the terminal faces of the first chip 210 and the second chip 220 are provided opposite to each other, and the terminal face of the first chip 210 is attached to the bottom of the first cavity. In general, the height of the chipset may be less than the height of the first cavity, so that a packaging layer 400 may be formed on the chipset through a subsequent process, so that the load applied to the chipset when manufacturing other hierarchical structures on the surface of the embedded packaging frame may be received, thereby preventing the chipset from being damaged, etc. In general, the back faces of the first chip 210 and the second chip 220 may be bonded by an adhesive material 230.

Then, a packaging layer 400 is formed in a gap between the chipset and the first cavity 101—step (c), as shown in FIG. 3D. In general, this step may include:
(c₁) a packaging layer 400 is formed in the gap between the chipset and the first cavity 101 and on the upper surface of the embedded packaging frame 100, as shown in FIG. 3C. In general, the packaging layer 400 may be selected from pure resins.
(c₁) thinning the packaging layer 400 to expose the upper surface of the first conductive post 102 of the embedded packaging frame 100 and the upper surface of the embedded packaging frame 100, and flush the upper surface of the packaging layer 400 with the upper surface of the first conductive post 102 and the upper surface of the embedded packaging frame 100. As such, it is possible to make the upper surface of the embedded packaging frame 100 have a good flatness, avoid the layer-adding conduction difficulty caused by device fluctuation, and facilitate the subsequent preparation of the first circuit layer 500 and the like on the upper surface of the embedded packaging frame 100. In general, the packaging material can be thinned by grinding or plasma etching.
(c₃) Opening the terminals 221 of the second chip 220 to form a blind hole 410 on the packaging layer 400. In general, the blind hole 410 is connected to the terminals 221 of the second chip 220 to facilitate electrical connection of the second chip 220 to a subsequently prepared first circuit layer 500 or the like. As such, the electrical connection between the chipset and the package substrate can be made with high integration and stability. In general, the terminals 221 of the second chip 220 may be windowed by laser drilling or the like to form a blind hole 410.

Next, a first circuit layer 500 and a second conductive post 600 are formed on the upper surface of the embedded packaging frame 100—step (d), as shown in FIG. 3E. In general, step (d) includes:
(d₁) forming a second metal seed layer on the upper surface of the embedded packaging frame 100 and the bottom and side wall of the blind hole 410; in general, the second metal seed layer may be formed by a sputtering process; the material of the second metal seed layer is not particularly limited and can be determined according to practical requirements, and generally can be titanium and copper;
(d₂) applying a third photoresist layer on the second metal seed layer, and exposing and developing the third photoresist layer to form a third feature pattern;
(d₃) electroplating the first circuit layer 500 in the third feature pattern; the first circuit layer 500 is generally connected to a terminal face of the second chip 220;
(d₄) removing the third photoresist layer, applying a fourth photoresist layer on the second metal seed layer, and exposing and developing the fourth photoresist layer to form a fourth feature pattern;
(d₅) electroplating a second conductive post 600 in the fourth feature pattern; a second conductive post 600 is generally provided corresponding to the first conductive post 102; and
(d₆) removing the third photoresist layer and the fourth photoresist layer and etching the exposed second metal seed layer.

Then, a first dielectric layer 700 is laminated on the upper surface of the first circuit layer 500—step (e), as shown in FIG. 3F. In general, step (e) includes:
laminating a first dielectric material on top of the first circuit layer 500. In general, the height of the first dielectric material exceeds the height of the second conductive post 600. As such, the second conductive posts 600 may be exposed by subsequent thinning, to flush the end face of the second conductive post 600 with the first dielectric layer 700, to facilitate subsequent manufacture of the hierarchy, etc.

The first dielectric material is thinned to expose the upper surface (end surface) of the second conductive post 600 to form a first dielectric layer 700 having an upper surface flush with the upper surface of the conductive post. In general, the first dielectric material may be thinned by grinding, plasma etching, or the like.

Next, a second circuit layer 800 is formed on an upper surface of the first dielectric layer 700, and a third circuit layer and a support post enclosure 310 provided around the embedded packaging frame are formed on a lower surface of the embedded packaging frame-step (f), as shown in FIG. 3G. In general, forming the second circuit layer 800 on the upper surface of the first dielectric layer 700 in the step (f) includes:
(f₁) forming a third metal seed layer on an upper surface of the first dielectric layer 700; in general, the third metal seed layer may be formed by a sputtering process. The material of the third metal seed layer is not particularly limited and can be determined according to actual requirements, and can generally be titanium and copper;
(f₁) applying a fifth photoresist layer on the third metal seed layer, and exposing and developing the fifth photoresist layer to form a fifth feature pattern;
(f₃) electroplating a second circuit layer 800 in the fifth feature pattern; and connecting the second circuit layer 800 to the first circuit layer 500 via the second conductive post 600;
(f₄) removing the fifth photoresist layer and etching the exposed third metal seed layer.

In general, in the step (f), forming a third circuit layer on the lower surface of the embedded packaging frame and a support post enclosure 310 provided around the embedded packaging frame includes:
(f₅) removing the adhesive layer 240 applied on the lower surface of the embedded packaging frame;
(f₆) forming a first metal seed layer on a lower surface of the embedded packaging frame; in general, the first metal seed layer may be formed by a sputtering process; the material of the first metal seed layer is not particularly limited and can be determined according to actual requirements, and can generally be titanium and copper;
(f₇) applying a first photoresist layer on the first metal seed layer, and exposing and developing the first photoresist layer to form a first feature pattern;
(f₈) electroplating a third circuit layer in the first feature pattern; the third circuit layer may include a functional circuit layer 910 and a circuit enclosure 920, and the support post enclosure 310 may be correspondingly provided on the circuit enclosure 920; wherein the surface of the sensing component 212 of the first chip 210 is exposed, i.e., the surface of the sensing component is not covered by the third circuit layer;
(f₉) removing the first photoresist layer, applying a second photoresist layer on the first metal seed layer, and exposing and developing the second photoresist layer to form a second feature pattern; and
(f₁₀) electroplating a support post enclosure 310 in the second feature pattern, as shown in FIG. 3H; in general, the support post enclosure 310 may be a copper support post enclosure 310, which may provide heat dissipation while being supported; taking the surface on which the embedded packaging frame is located as a reference surface, the forward projection of the support post enclosure 310 on the reference surface partially overlaps with the forward projection of the line enclosure 920 on the reference surface;
(f₁₁) removing the second photoresist layer and etching the exposed first metal seed layer;
then, a through-hole 103 is formed sequentially penetrating the first dielectric layer 700 and the embedded packaging frame in the height direction to form a first packaging structure with the chipset and a second packaging structure without the chipset-step (g), as shown in FIG. 3I. The through-hole 103 through which the first chip 210 (i.e., the sensing chip) can sense an external environmental load and then output an electrical signal to the second chip 220 may be formed by mechanical drilling or the like.

Then, a passive element 250 is fitted on the lower surface of the second packaging structure; a packaging layer 300 is formed on the lower surface of the embedded packaging frame and the outside of the circuit enclosure 920 and the support post enclosure 310—step (h), as shown in FIG. 2. In general, the passive element 250 may be attached to the lower surface of a functional circuit layer 910 in the third circuit layer.

In general, forming a packaging layer 300 on the lower surface of the embedded packaging frame and the outside of the circuit enclosure 920 and the support post enclosure 310 includes:
laminating a second dielectric layer 350 on the lower surface of the embedded packaging frame and the outside of the circuit enclosure 920 and the support post enclosure 310 to form a second cavity 340 for receiving the passive element 250. As such, the first chip 210 (i.e., the MEMS sensing chip) in the chipset can sense an external environmental load through the second cavity 340 and the through-hole 103 and then output an electrical signal to the second chip 220 (i.e., an ASIC chip). The ASIC chip amplifies and modulates the electrical signal output by the MEMS chip into the required standard output signal. In general, the second dielectric layer 350 may be a covering film. The use of a covering film can provide protection and isolation. Further, the packaging layer 300 has high transparency and smoothness, temperature resistance and weather resistance, antistatic properties, etc.

A packaging layer 300 is laminated on the surface of the second dielectric layer 350.

A packaged cavity structure and a manufacturing method thereof provided in the embodiments of the present application, wherein a high-density integrated package is achieved by embedding and packaging an MEMS sensing chip and an ASIC chip in a package substrate in a stacked manner; a copper post enclosure is provided on the top of the embedded package substrate, and a packaged cavity is formed after packaging; the sensing part of the MEMS sensing chip is exposed, and sensing with the external environment is achieved through the packaged cavity structure and the hole through the substrate. Thus, the technical problems in the prior art, such as low efficiency, high cost, poor precision and the inability to miniaturize the packaging volume, are solved. Having a high-density integrated package capable of realizing the MEMS sensing chip and the ASIC chip; the processing efficiency is improved and the cost is reduced by processing the plastic cavity structure at panel level. By setting a copper post enclosure, a covering film is laminated and same is packaged to form a packaged cavity, compared with the cavity formed by the protective cover, the processing precision is higher and can meet the requirements of high-density integrated packaging.

A person skilled in the art will appreciate that the discussion of any embodiment above is merely exemplary and is not intended to imply that the scope of the disclosure, including the claims, is limited to these examples; combinations of features in the above embodiments, or between different embodiments, may also be made within the spirit of the present disclosure, the steps may be implemented in any order, and there may be many other variations of the different aspects of the embodiments of the present disclosure as described above, which are not provided in detail for clarity.

While the present disclosure has been described in conjunction with specific embodiments thereof, it is evident that many alternatives, modifications, and variations will be apparent to a person skilled in the art in light of the foregoing description.

The disclosed embodiments are intended to embrace all such alternatives, modifications and variances which fall within the broad scope of the appended claims. Accordingly, it is intended to embrace all such alternatives, modifications, equivalents, improvements, that fall within the spirit and scope of the disclosed embodiments.

What is claimed is:

1. A method for manufacturing a packaged cavity structure, the method comprising:
(a) preparing an embedded packaging frame; the embedded packaging frame comprising a first cavity and a first conductive post respectively penetrating an insulation layer along a height direction;
(b) embedding a chipset at the bottom of the first cavity; the chipset comprising a first chip and a second chip provided in a stack, and the back faces of the first chip and the second chip being adhered to each other so that the terminal faces thereof being opposite to each other;
(c) forming a packaging layer in a gap between the chipset and the first cavity; the packaging layer having a blind hole exposing a terminal of the second chip;
(d) forming a first circuit layer and a second conductive post on an upper surface of the embedded packaging frame, wherein the first circuit layer is in conductive connection with a terminal of the second chip;
(e) laminating a first dielectric layer on an upper surface of the first circuit layer; wherein an upper surface of the first dielectric layer is flush with an upper surface of the second conductive post;
(f) forming a second circuit layer on an upper surface of the first dielectric layer, forming a third circuit layer on a lower surface of the embedded packaging frame, and forming a support post enclosure surrounding the first cavity on the third circuit layer;
(g) forming a through-hole penetrating the first dielectric layer and the insulation layer successively in a height direction, wherein the through-hole is surrounded by the above-mentioned support post enclosure; and
(h) forming a packaging layer along an outer side of the support post enclosure under the embedded packaging frame, and forming a second cavity between the packaging layer and the embedded packaging frame.

2. The method for manufacturing a packaged cavity structure according to claim 1, wherein the step (h) further comprises:
applying a second dielectric layer along the outside of the support post enclosure under the embedded packaging frame to form the second cavity; and
laminating the packaging layer on the second dielectric layer.

3. The method for manufacturing a packaged cavity structure according to claim 2, wherein the second dielectric layer is a covering film.

4. The method for manufacturing a packaged cavity structure according to claim 1, wherein the first chip is a sensor chip, wherein a sensing part surface of the first chip is exposed to the second cavity to communicate with the outside through the through-hole.

5. The method for manufacturing a packaged cavity structure according to claim 1, wherein the third circuit layer comprises a functional circuit layer and a circuit enclosure, and
the support post enclosure is electroplated on the circuit enclosure.

6. The method for manufacturing a packaged cavity structure according to claim 1,
wherein the support post enclosure is a copper post enclosure.

7. The method for manufacturing a packaged cavity structure according to claim 1, wherein the step (f) further comprises:
forming a first metal seed layer on a lower surface of the embedded packaging frame;
applying a first photoresist layer on the first metal seed layer, exposing and developing the first photoresist layer to form a first feature pattern;
electroplating a third circuit layer in the first feature pattern;
removing the first photoresist layer, applying a second photoresist layer on the first metal seed layer, exposing and developing the second photoresist layer to form a second feature pattern;
electroplating a support post enclosure in the second feature pattern; and
removing the second photoresist layer and etching the exposed first metal seed layer.

8. The method for manufacturing a packaged cavity structure according to claim 1, wherein the step (b) comprises:
applying an adhesive layer on a lower surface of the embedded packaging frame; and
attaching a terminal face of the first chip to the exposed adhesive layer in the first cavity, and attaching a back face of the second chip on a back face of the first chip to attach the chipset at the bottom of the first cavity.

9. The method for manufacturing a packaged cavity structure according to claim 1, wherein the step (c) further comprises:
forming a packaging layer in a gap between the chipset and the first cavity and on an upper surface of the embedded support frame;
thinning the packaging layer to expose a conductive post of the embedded support frame; and
forming a blind hole in the packaging layer to expose the terminals of the second chip.

10. A packaged cavity structure comprising:
an embedded packaging frame having a first cavity and a first conductive post respectively penetrating an insulation layer in a height direction;
a chipset provided within the first cavity, the chipset comprising a first chip and a second chip provided in a back-to-back stack;
a first circuit layer provided on an upper surface of the embedded packaging frame;
a first dielectric layer provided on the first circuit layer;
a second circuit layer provided on the first dielectric layer;
a through-hole penetrating the first dielectric layer and the insulation layer;
a third circuit layer on a lower surface of the embedded packaging frame;
a support post enclosure on the third circuit layer;
a packaging layer formed along the outside of the support post enclosure; and
a second cavity configured to communicate with the through-hole and formed between the packaging layer and the lower surface of the embedded packaging frame.

11. The packaged cavity structure according to claim 10, wherein the first chip is a sensor chip, and
a sensing part surface of the first chip is exposed to the second cavity to communicate with the outside through the through-hole.

12. The packaged cavity structure according to claim 10, further comprising a second dielectric layer between the packaging layer and the second cavity.

13. The packaged cavity structure according to claim 12, wherein the second dielectric layer is a covering film.

14. The packaged cavity structure according to claim 10, wherein the first chip is selected from a micro-electromechanical system (MEMS) sensor chip, and the second chip is selected from an application-specific integrated circuit (ASIC) chip.
